(19) United States
(12) Patent Application Publication
(10) Pub. No.: US 2010/0151696 A1
(43) Pub. Date: Jun. 17, 2010

(54) MANUFACTURING METHOD FOR SEMICONDUCTOR DEVICE AND HEAT TREATMENT APPARATUS

(76) Inventors: Takayuki ITO, Oita-ken (JP); Masato Fukumoto, Oita-ken (JP); Kunihiro Miyazaki, Oita-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/635,411

(22) Filed: Dec. 10, 2009

(30) Foreign Application Priority Data
Dec. 11, 2008 (JP) 2008-315562

(51) Int. Cl. H01L 21/268; B01J 19/12

(52) U.S. Cl. 438/798; 250/492.2; 257/E21.347

(57) ABSTRACT

A manufacturing method for a semiconductor device, includes, forming an element region on a front surface of a semiconductor substrate, performing a first heat treatment by irradiating first irradiation light having a first irradiation energy density onto the front surface of the semiconductor substrate with a pulse width of 0.1 to 100 msec at the temperature of 1000° C. or less; and performing a second heat treatment by irradiating second irradiation light having a second irradiation energy density onto the surface of the semiconductor substrate with a pulse width of 0.1 to 100 msec at the temperature higher than the temperature in the first heat treatment.

### CROSS-REFERENCE TO RELATED APPLICATION

This application is based upon and claims the benefit of priority from the prior Japanese Patent Application No. 2008-315562 filed on Dec. 11, 2008, the entire contents of which are incorporated herein by reference.

### BACKGROUND OF THE INVENTION

The present invention relates to a manufacturing method for a semiconductor device and a heat treatment apparatus used in an activation annealing treatment of an impurity ion injected into a semiconductor substrate.

In recent years, with a size decrease of an element, an improvement in performance of a semiconductor device has been studied. Since influence of parasitic resistance of an MOSFET constituting the semiconductor device and a short channel effect increases with the size decrease, it has been required to form low resistance and shallow (shallower junction) impurity diffusion layer in a semiconductor substrate.

In order to decrease resistance of the impurity diffusion layer, an activation heat treatment needs to be performed at a high temperature after impurities are injected into a surface of the semiconductor substrate. In rapid thermal annealing (RTA) in the related art, however, since impurities are diffused, it is difficult to achieve both low resistance and shallow junction. Accordingly, as disclosed in Japanese Patent Application Laid-Open (JP-A) No. 2004-63574 ([0006], etc.), an annealing method using flash lamp light capable of instantly supplying thermal energy has been studied.

A short flash lamp can emit light with a pulse width of sub-millisecond as shortest. Accordingly, an impurity ion that is injected into the surface of the semiconductor substrate can be activated without varying a distribution of the impurity ion.

However, in order to sufficiently activate impurities, a large irradiation energy density of, for example, 20 J/cm² or more is needed. If flash lamp light is irradiated with a pulse width of 100 msec or less to heat the semiconductor substrate, the temperature of the surface of the semiconductor substrate rapidly rises to 1200° C. or more. Accordingly, a temperature difference is generated between a front surface and a rear surface of the semiconductor substrate, and thermal stress is generated in the semiconductor substrate. Due to an increase in the diameter of the semiconductor substrate, the total amount of thermal stress generated also increases. For this reason, damage such as slip or dislocation may be easily caused, and the semiconductor substrate may be cracked. As a result, a yield may be lowered.

That is, in order to sufficiently activate the impurities, it is required to increase an irradiation energy density and increase the temperature of the surface of the semiconductor substrate. However, the semiconductor substrate may be easily cracked due to an increase in the temperature. As such, in the annealing using the flash lamp light, a process window that forms a shallow impurity diffusion region having low resistance without causing damage to the semiconductor substrate is narrow.

On the other hand, as disclosed in Japanese Patent Application Publication (JP-B) No. 62-44847, Japanese Patent Application Publication (JP-B) No. 2-5295, and Japanese Patent Application Laid-Open (JP-A) No. 2000-349038 ([0013], [0020], etc.), when annealing is performed using a halogen lamp, a temperature distribution of the rear surface of the semiconductor substrate is controlled. However, thermal stress generated due to the annealing is significantly different from thermal stress generated when the flash lamp light is irradiated with a pulse width of 100 msec or less. Accordingly, if the flash lamp is used, it is difficult to form a shallow impurity diffusion region having low resistance with high in-plane uniformity, without causing damage to the semiconductor substrate, by only heating the outer circumferential portion as described in these documents.

### SUMMARY

According to an aspect of the invention, there is provided a method of manufacturing a semiconductor device, including: forming an element region on a front surface of a semiconductor substrate; performing a first heat treatment by irradiating first irradiation light having a first irradiation energy density onto the front surface of the semiconductor substrate with a pulse width of 0.1 to 100 msec at the temperature of 1000° C. or less; and performing a second heat treatment by irradiating second irradiation light having a second irradiation energy density onto the surface of the semiconductor substrate with a pulse width of 0.1 to 100 msec at the temperature higher than the temperature in the first heat treatment.

According to another aspect of the invention, there is provided a method of manufacturing a semiconductor device, including: forming an element region on a front surface of a semiconductor substrate; irradiating first irradiation light having a predetermined irradiation energy density onto a rear surface of the semiconductor substrate with a pulse width of 0.1 to 100 msec to form a ductile region on the rear surface of the semiconductor substrate; and performing a heat treatment by irradiating second irradiation light having a predetermined irradiation energy density onto the surface of the semiconductor substrate with a pulse width of 0.1 to 100 msec after forming the ductile region.

According to still another aspect of the invention, there is provided a heat treatment apparatus, including: one or more chambers configured to perform heat treatment to a semiconductor substrate having an element region on a front surface; one or more stages on which the semiconductor substrate is mounted, disposed in the one or more chambers; irradiation mechanism configured to irradiate a first irradiation light having a predetermined irradiation energy density with a pulse width of 0.1 to 100 msec onto a rear surface of the semiconductor substrate, and a second irradiation light having a predetermined irradiation energy density with a pulse width of 0.1 to 100 msec onto a front surface of the semiconductor substrate on which the first irradiation light is irradiated; a movement mechanism configured to transfer or reverse the semiconductor substrate.

### BRIEF DESCRIPTION OF THE DRAWINGS

FIGS. 1A to 1G are cross-sectional views illustrating processes of manufacturing a semiconductor device according to an embodiment of the present invention;

FIG. 2 is a graph showing a temperature profile of activation annealing by a Xe flash lamp;

FIG. 3 is a graph showing a light emission spectrum of Xe flash lamp light;

FIG. 4 is a diagram illustrating a structure of a heat treatment apparatus that is used in activation annealing in an embodiment of the present invention;

FIG. 5 is a graph showing a heat treatment condition range in an embodiment of the present invention;

FIG. 6 is a diagram illustrating a sheet resistance distribution in an embodiment of the present invention;

FIG. 7 is a graph showing a heat treatment condition range in a comparative example;

FIG. 8 is a diagram illustrating a sheet resistance distribution in a comparative example;

FIG. 9 is a graph showing a heat treatment condition range in a comparative example;

FIG. 10 is a diagram illustrating a sheet resistance distribution in a comparative example;

FIG. 11 is a diagram illustrating a state of an outer circumferential portion of a semiconductor substrate in activation annealing in an embodiment of the present invention;

FIG. 12 is a diagram illustrating a structure of a heat treatment apparatus that is used in activation annealing in an embodiment of the present invention;

FIG. 13 is a diagram illustrating a state of an outer circumferential portion of a semiconductor substrate in activation annealing in an embodiment of the present invention;

FIG. 14 is a diagram illustrating a structure of a heat treatment apparatus that is used in activation annealing in an embodiment of the present invention;

FIG. 15 is a diagram illustrating a state of an outer circumferential portion of a semiconductor substrate in activation annealing in an embodiment of the present invention;

FIGS. 16A to 16C are diagrams illustrating a structure of a heat treatment apparatus that is used in activation annealing in an embodiment of the present invention;

FIG. 17 is a diagram showing a flow of activation annealing in an embodiment of the present invention;

FIG. 18 is a graph showing a heat treatment condition range in an embodiment of the present invention;

FIG. 19 is a diagram illustrating a state of a semiconductor substrate in activation annealing in a comparative example;

FIG. 20 is a diagram illustrating a state of a semiconductor substrate in activation annealing in an embodiment of the present invention;

FIGS. 21 to 23 are diagrams illustrating a structure of a heat treatment apparatus that is used in activation annealing in an embodiment of the present invention;

FIG. 24 is a diagram showing a flow of activation annealing in an embodiment of the present invention;

FIG. 25 is a graph showing a thermal history of activation annealing in an embodiment of the present invention;

FIG. 26 is a graph showing a heat treatment condition range in a relationship between an irradiation energy density and an auxiliary-heating temperature of activation annealing in an embodiment of the present invention;

FIG. 27A is a schematic diagram illustrating an influence of damage in a rear surface of a semiconductor substrate by activation annealing in a comparative example;

FIG. 27B is a schematic diagram illustrating an influence of damage in a rear surface of a semiconductor substrate by activation annealing in an embodiment of the present invention; and

FIGS. 28A and 28B are graphs showing a thermal history of activation annealing in an embodiment of the present invention.

### DETAILED DESCRIPTION

Reference will now be made in detail to the present embodiment of the invention, an example of which is illustrated in the drawings. Wherever possible, the same reference numbers will be used throughout the drawing to refer to the same or like parts.

Hereinafter, embodiments of the present invention will be described in detail with reference to the accompanying drawings.

### First Embodiment

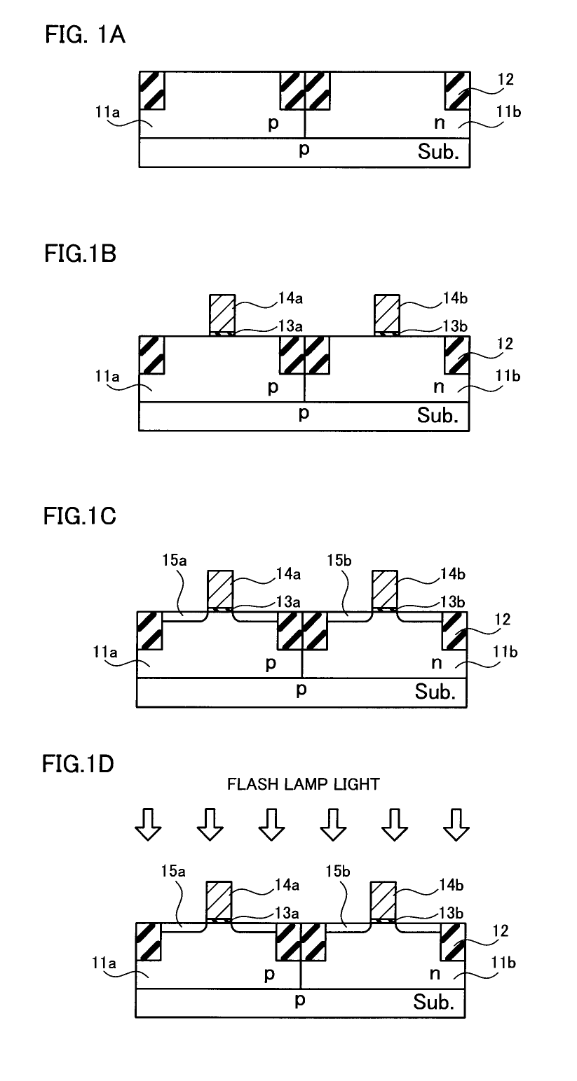

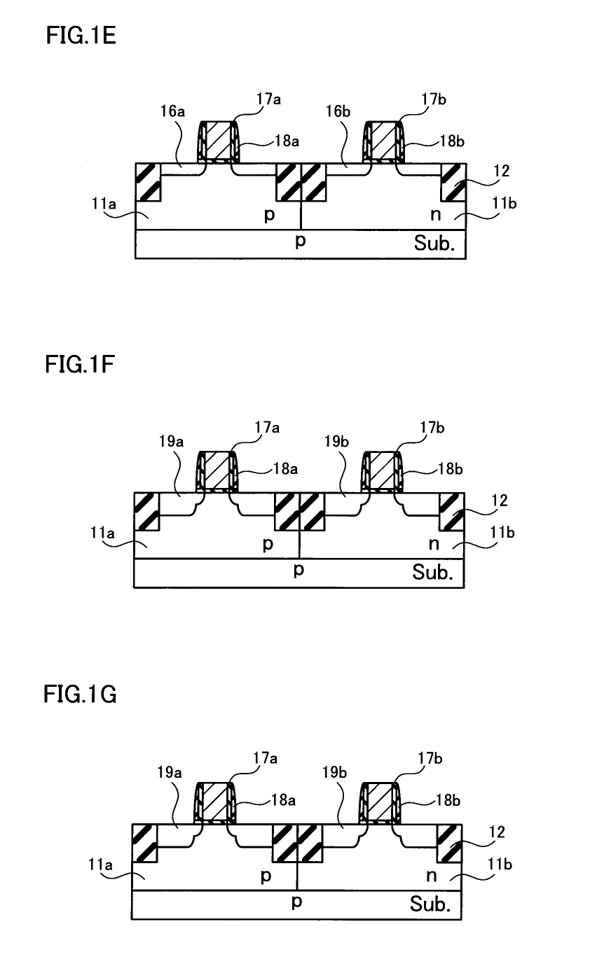

FIGS. 1A to 1G are cross-sectional views illustrating processes of manufacturing a CMOS transistor, as processes of manufacturing a semiconductor device according to this embodiment. First, as illustrated in FIG. 1A, in a semiconductor substrate (Sub.) made of a p-type Si, a p-well layer 11a and an n-well layer 11b are formed in an nMOSFET region and a pMOSFET region, respectively. An element isolation region 12 having a shallow trench isolation (STI) structure is formed around the n-well layer lib. In this embodiment, a front surface of the semiconductor substrate is a surface formed an nMOSFET region and a pMOSFET region.

As illustrated in FIG. 1B, an insulating film, such as an Si oxide film, which becomes gate insulating films 13a and 13b, is formed on a front surface of the semiconductor substrate (Sub.). On the insulating film, a polycrystalline Si (poly-Si) film, which becomes gate electrodes 14a and 14b, is deposited by, for example, low pressure chemical vapor deposition (LPCVD) method. Then, etching is selectively performed using photolithography and reactive ion etching (RIE), and the gate electrodes 14a and 14b and the gate insulating films 13a and 13b are formed.

Ions are injected using the gate electrodes 14a and 14b as a mask. The pMOSFET region is masked by a photo resist film, and a V-group atom, which becomes an n-type impurity, for example, As is injected. According to an ion injection condition of As, for example, acceleration energy is 2 keV and a dose amount is 1×10¹⁵ cm⁻². The photo resist film of the pMOSFET region is removed, the nMOSFET region is masked by a photo resist film, and an III-group atom, which becomes an n-type impurity, for example, B is injected. According to an ion injection condition of B, for example, acceleration energy is 0.5 keV and a dose amount is 1×10¹⁵ cm⁻². Then, the photo resist film of the nMOSFET region is removed. In this way, as illustrated in FIG. 10, shallow impurity injection layers 15a and 15b are formed between the gate insulating films 13a and 13b and the element isolation region 12.

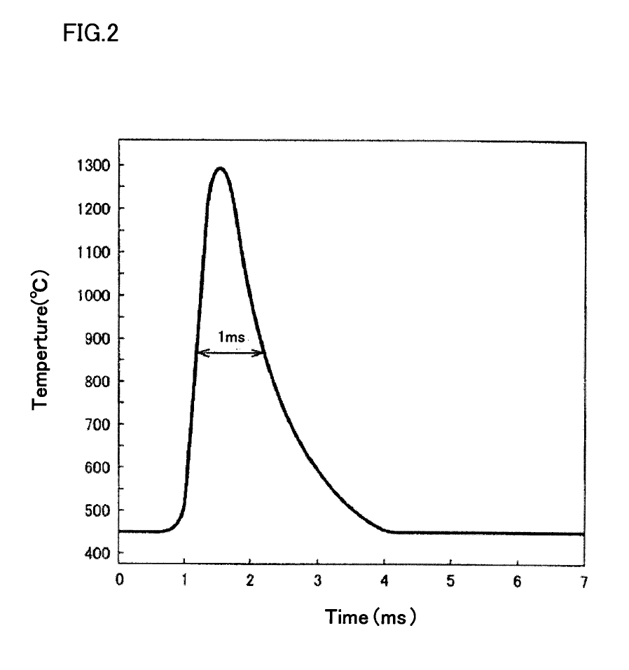

Activation annealing of the injected impurity ion is performed. In this process, a xenon (Xe) flash lamp that has a temperature profile of a pulse width (half-value width) of 1 msec and the highest reached temperature of about 1300° C. as shown in FIG. 2 is used. Using the Xe flash lamp, rapid rise and fall of the temperature is possible, a rising and falling time of the temperature in a range of 450 to 1300° C. being in a range of 0.1 to 100 msec (0.5 to 50 msec). By such rapid rise and fall of the temperature, activation annealing of 900° C. or more can be performed in a very short time. Accordingly, the diffusion length of the impurity by the activation annealing can be suppressed at 5 nm or less, enabling formation of a shallow pn junction.

Using an infrared lamp, such as a halogen lamp, which is used in Spike RTA (Rapid Thermal Annealing), a rising and falling time of the temperature in a range of 450 to 1300° C. is 10 seconds or more (for example, 15 seconds), while a rising and falling time of the temperature by 100° C. in a range of 900 to 1300° C. is 2 to 3 seconds. Therefore, the temperature rising and falling rates are significantly different from the Xe flash lamp.

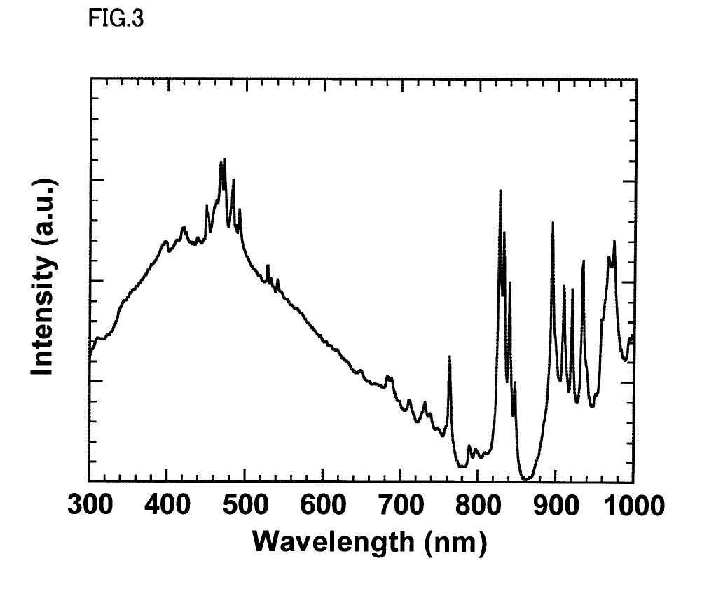

The Xe flash lamp light has a light emission spectrum similar to that of white light, as shown in FIG. 3, and its main intensity peak wavelength is in a range of 400 to 500 nm. Light having a wavelength of 1 μm or less that includes the peak wavelength is absorbed by a region within 0.1 μm from the front surface of the semiconductor substrate (sub.), and a rapid temperature rise is locally generated in a region within several tens of micrometers from the front surface.

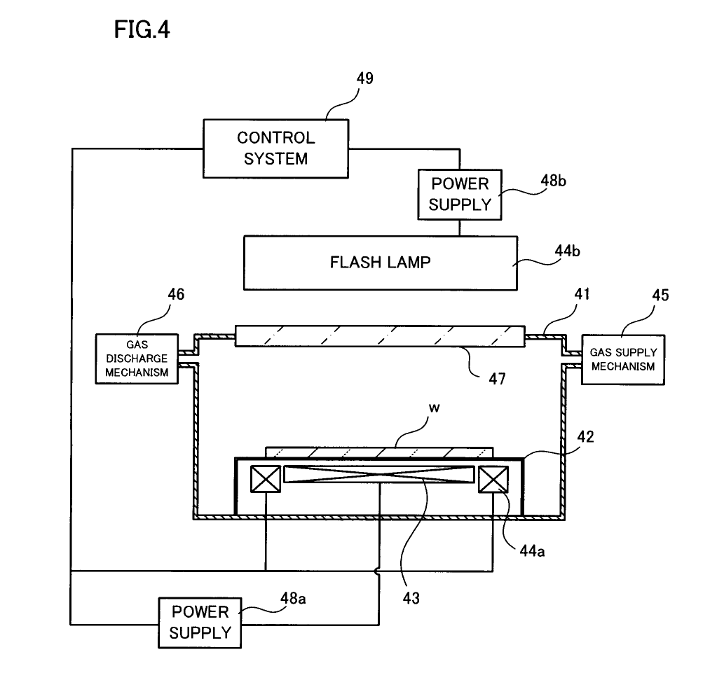

By using the Xe flash lamp, activation annealing of impurity ions is performed by a heat treatment apparatus such as one illustrated in FIG. 4. In the heat treatment apparatus, a chamber 41 made of, for example, metal, such as stainless steel where activation annealing is performed to the semiconductor substrate w and a stage 42 to mount the semiconductor substrate w thereon are disposed. The stage 42 is made of aluminum nitride (AlN), silicon carbide (SiC), quartz or the like. Below the stage 42, an auxiliary heating source 43 that auxiliary-heats the semiconductor substrate w from the rear surface and has a smaller area than the semiconductor substrate w, and a light source (flash lamp) 44a that is an irradiating mechanism for heating an outer circumferential portion of the rear surface of the semiconductor substrate ware provided. As the auxiliary heating source 43, a metal buried heater, such as nichrome wire, a halogen lamp or the like is used. Further, a gas supply mechanism 45 for supplying inert gas or the like into the chamber 41 and a gas discharge mechanism 46 for discharging gas therefrom are provided. On the top of the chamber 41, a transparent window 47 made of synthetic quartz or the like is provided.

Above the chamber 41, a light source (flash lamp) 44b is provided at a distance from the chamber 41 for irradiating emission light in the chamber 41 through the transparent window 47, in a state where airtightness of the chamber 41 is held, to heat the semiconductor substrate w. The light sources 44a and 44b are connected to power supplies 48a and 48b, such as pulse power supplies, which drive the light sources 44a and 44b. The light sources 44a and 44b a reconnected to a control system 49 that controls pulse widths and irradiation energy densities of the light sources 44a and 44b, and an output of the auxiliary heating source 43.

In the heat treatment apparatus, the semiconductor substrate w where an impurity injection layer is formed is loaded in the chamber 41 and mount on the stage 42. In order to produce a non-oxygenated atmosphere, inert gas is introduced by the gas supply mechanism 45 and is then discharged by the gas discharge mechanism 46. The auxiliary heating source 43 and the light sources 44a and 44b are controlled by the control system 49 to heat the semiconductor substrate w.

By the auxiliary heating source 43, the rear surface of the semiconductor substrate w is auxiliary-heated at 450° C. While keeping this state, the power supply 48b is controlled by the control system 49, and flash lamp light that is irradiation light from the light source 44b is irradiated onto the front surface of the semiconductor substrate w through the transparent window 47. An irradiation condition where a pulse width is 1 msec and an irradiation energy density is 30 J/cm² is used. In this process, in synchronization with the irradiation from the light source 44b, the power supply 48a is controlled by the control system 49 to irradiate flash lamp light that is irradiation light from the light source 44a onto the outer circumferential portion of the rear surface of the semiconductor substrate w through the stage 42. An irradiation condition where a pulse width is 1 msec and an irradiation energy density is 30 J/cm² is used.

By irradiating the flash lamp light in this way, the temperature of the front surface of the semiconductor substrate w that is measured by a high-speed pyrometer becomes 1200° C. at a central portion of the front surface and 1300° C. at the outer circumferential portion of the rear surface of 5 mm from the outer circumference (for example, position at 5 mm from an outer end). The impurity ions As and B that are injected into the impurity injection layers 15a and 15b, respectively, are introduced by being substituted in lattice positions and activated. In this way, as illustrated in FIG. 1D, shallow active layers 16a and 16b are formed between the gate insulating films 13a and 13b and the element isolation region 12, respectively.

An oxide silicon (SiO₂) film and a nitride silicon (Si₃N₄) film are sequentially deposited using LPCVD method. Then, the oxide silicon (SiO₂) film and the nitride silicon (Si₃N₄) film are etched using the RIE method. In this way, as illustrated in FIG. 1E, sidewall spacers 17a and 17b made of oxide silicon (SiO₂) films and sidewall spacers 18a and 18b made of nitride silicon (Si₃N₄) films are formed on the sides of the gate electrodes 14a and 14b, respectively.

Ions are injected using the gate electrodes 14a and 14b and the sidewall spacers 17a, 17b, 18a, and 18b as a mask. First, the pMOSFET region is masked by a photo resist film, and a V-group atom, which becomes an n-type impurity, for example, As is injected. According to an ion injection condition of As, for example, acceleration energy is 20 keV and a dose amount is 4×10¹⁵ cm⁻². Then, the photo resist film of the pMOSFET region is removed, the nMOSFET region is masked with a photo resist film, and an III-group atom, which becomes an n-type impurity, for example, B is injected. According to an ion injection condition of B, for example, acceleration energy is 2 keV and a dose amount is 4×10¹⁵ cm⁻². Then, the photo resist film of the nMOSFET region is removed. In this way, as illustrated in FIG. 1F, deep impurity injection layers 19a and 19b are formed between the gate electrodes 14a and 14b and the element isolation film 12 apart from the area below the gate electrodes 14a and 14b.

Activation annealing of the injected impurity ion is performed. Similarly to the activation annealing of the shallow impurity injection layers, the rear surface of the semiconductor substrate w where the impurity injection layer is formed is auxiliary-heated at 450° C. While keeping this state, the flash lamp light is irradiated onto the front surface of the semiconductor substrate w under the condition where a pulse width is 1 msec and an irradiation energy density is 30 J/cm². In this process, in synchronization with the flash lamp light, the flash lamp light is irradiated onto the outer circumferential portion of the rear surface of the semiconductor substrate w under the condition where a pulse width is 1 msec and an irradiation energy density is 30 J/cm², for example.

By irradiating the flash lamp light in this way, the temperature of the front surface of the semiconductor substrate w that is measured in the same manner becomes 1200° C. at a central portion of the front surface and 1300° C. at the outer circumferential portion of the rear surface. Then, the impurity ions As and B that are injected into the impurity injection layers 19a and 19b, respectively, are introduced by being substituted in lattice positions and activated. In this way, as illustrated in FIG. 1G, n-type and p-type active layers 20a and 20b are formed between the gate insulating films 13a and 13b and the element isolation region 12, respectively.

An interlayer insulating film (not illustrated) made of SiO₂ is formed on the semiconductor substrate where the active layers are formed, and contacts (not illustrated) are formed on the gate electrodes 14a and 14b and the active layers 20a and 20b corresponding to source/drain regions and are connected to wiring lines (not illustrated). In this way, a CMOS transistor is formed.

In this embodiment, an irradiation energy density range of the flash lamp light that achieves a desired activation rate in high-temperature activation annealing depends on the auxiliary-heating temperature, and a heat treatment condition range (process window) is as shown in FIG. 5.

That is, when an irradiation energy density is smaller than a lower limit of the heat treatment condition range, activation of the impurities becomes insufficient, and it is difficult to form a superior low resistance layer where there is no ion injection defect. On the other hand, if the irradiation energy density exceeds an upper limit of the heat treatment condition range, the semiconductor substrate w may be broken. Accordingly, the irradiation energy density needs to be within a heat treatment condition range, and the width is preferably large in consideration of a process margin.

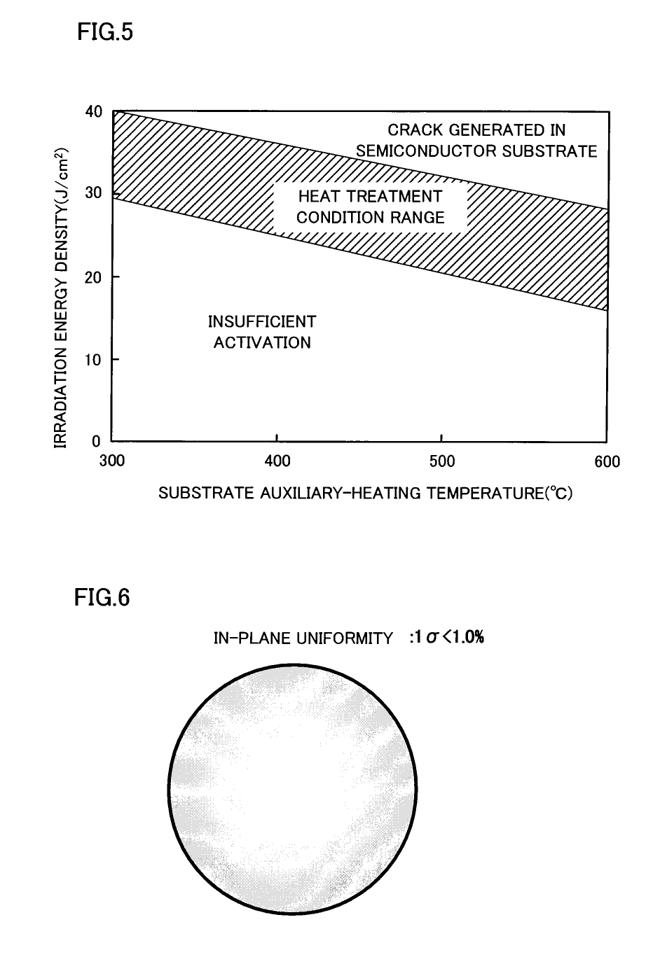

FIG. 6 illustrates a sheet resistance distribution that depends on a temperature distribution of the semiconductor substrate. Lower resistance is shown darker.

As illustrated in FIG. 6, it can be seen that the distribution is almost uniform without shading, and in-plane uniformity of the effective annealing temperature is as good as 1σ<1.0%.

On the other hand, as a first comparative example, the entire rear surface of the semiconductor substrate was auxiliary-heated at 450° C., such that the in-plane temperature distribution became uniform. Similarly to the first embodiment, the flash lamp light was irradiated onto only the front surface of the semiconductor substrate under the condition where a pulse width was 1 msec and an irradiation energy density was 30 J/cm², and the temperature of the front surface was increased to 1200° C. As a result, the semiconductor substrate was broken due to a predetermined number of processes. The outer circumferential portion was observed that dislocation and slip were generated at a high density.

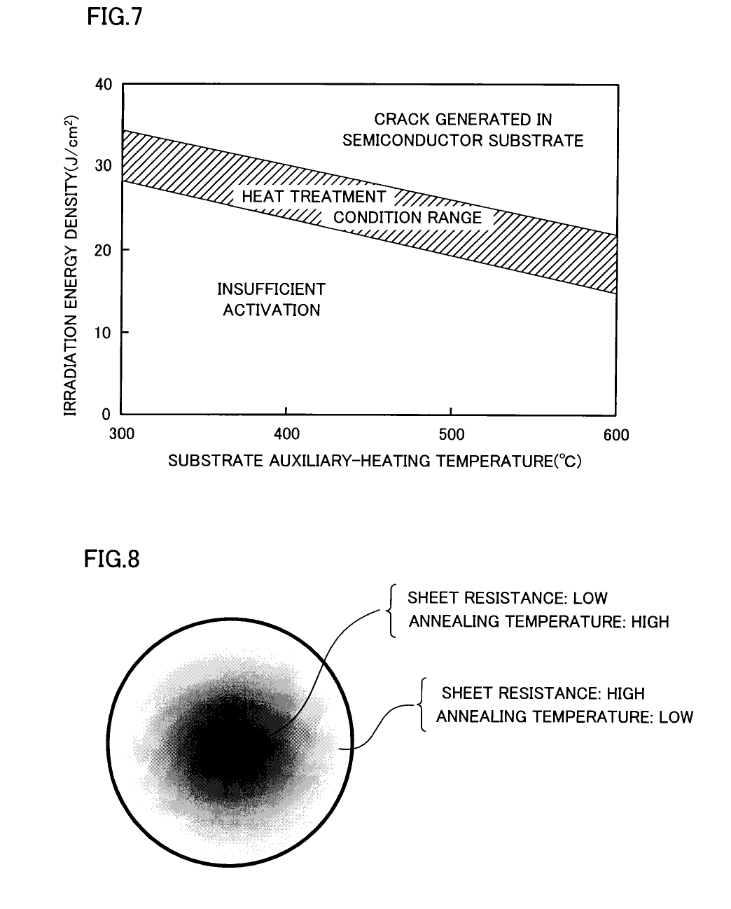

Further, the auxiliary-heating temperature was set to 500° C. and 550° C., and the flash lamp light was irradiated onto the front surface of the semiconductor substrate. As a result, the semiconductor substrate was broken due to the predetermined number of processes. When the auxiliary-heating temperature was set to 550° C., the semiconductor substrate was broken in the first process, and even when the irradiation energy density was lowered, the semiconductor substrate was broken. The heat treatment condition range (process window) in this process is shown in FIG. 7. As compared with FIG. 5, it can be seen that the heat treatment condition range is reduced.

The reason for the result is considered as follows. In the first comparative example, the auxiliary heating is performed such that the in-plane temperature distribution becomes uniform. However, if heating is made from the top surface of the semiconductor substrate using the flash lamp light, a temperature difference is generated between the central portion and the outer circumferential portion of the semiconductor substrate. This is because solid angles of the top surface of the semiconductor substrate with the flash lamp are different from each other in the central portion and the outer circumferential portion of the semiconductor substrate, and thus, if the same temperature balance is set, the temperature of the central portion is likely to become higher and the heat is likely to be released from the outer circumferential portion. In FIG. 8, a sheet resistance distribution at this time is illustrated by shading in the same manner as in the first embodiment. As illustrated in FIG. 8, sheet resistance becomes low and the effective annealing temperature becomes high in the central portion of the semiconductor substrate while the sheet resistance becomes high and the effective annealing temperature becomes low in the outer circumferential portion.

From a viewpoint of thermal stress, since tensile stress acts in the outer circumferential portion of the semiconductor substrate, the slip and the dislocation are induced from the outer circumferential portion of the semiconductor substrate where the strength is relatively weak. Finally, a crack is developed and the semiconductor substrate is broken. The crack of the semiconductor substrate from the outer circumferential portion is actually demonstrated by an observation using a high-speed camera. It is considered that the semiconductor substrate starts to be broken from a place where scratches or defects due to external causes are generated, and the breakage is furthered by tensile stress of the outer circumferential portion increased in annealing.

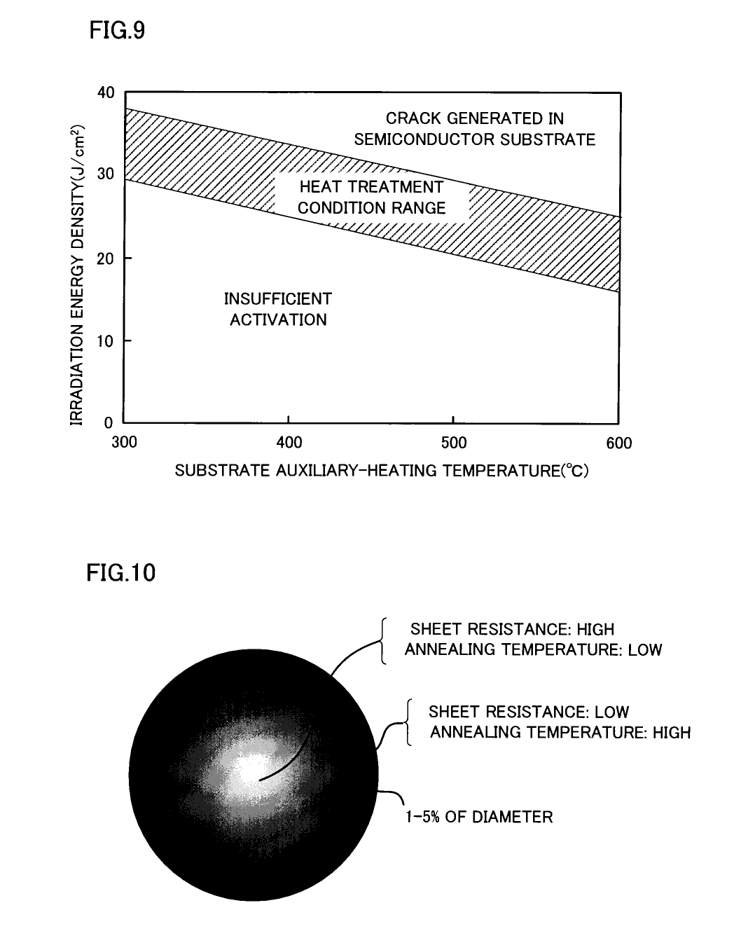

Accordingly, in a second comparative example, the light source (flash lamp) 44b or the auxiliary heating source 43 was controlled such that the temperature of the outer circumferential portion of the semiconductor substrate became higher than the temperature of the central portion, and annealing was performed in a state where temperature gradient was added to the in-plane temperature distribution. Specifically, the semiconductor substrate was heated by irradiating the flash lamp light under the condition where a pulse width was 1 msec and an irradiation energy density was 30 J/cm², such that the temperature of the central portion of the semiconductor substrate became 1200° C. and the temperature of the outer circumferential portion became 1300° C. As a result, even though the predetermined number of processes were performed, the semiconductor substrate was not broken. The heat treatment condition range (process window) in this process is shown in FIG. 9. As compared with FIG. 5, the heat treatment condition range is slightly reduced. However, as compared with FIG. 7, the heat treatment condition range is increased.

From a viewpoint of thermal stress, compressive stress acts in the outer circumferential portion of the semiconductor substrate, and cracks originating from starches or defects due to external causes are prevented from progressing. However, as in FIG. 10 in which the sheet resistance distribution in this process is shown by shading in the same manner as in the first embodiment, the in-plane temperature uniformity is deteriorated.

From the above results, in this embodiment, the reason why crack resistance of the semiconductor substrate is improved is considered.

In the outer circumferential portion of the rear surface of the semiconductor substrate, scratches are generated due to external causes such as in a device transfer system, and the number of scratches is large. In addition, the tensile stress at the rear surface side of the semiconductor substrate increases due to the temperature difference between the front and rear surfaces of the semiconductor substrate. Since the rear surface side is maintained at low auxiliary-heating temperature that is lower than 600° C., the rear surface side remains in a brittle region. When the thermal stress is concentrated on the outer circumference of the semiconductor substrate, the cracks are developed from the scratches to release the thermal stress. As a result, the semiconductor substrate is broken.

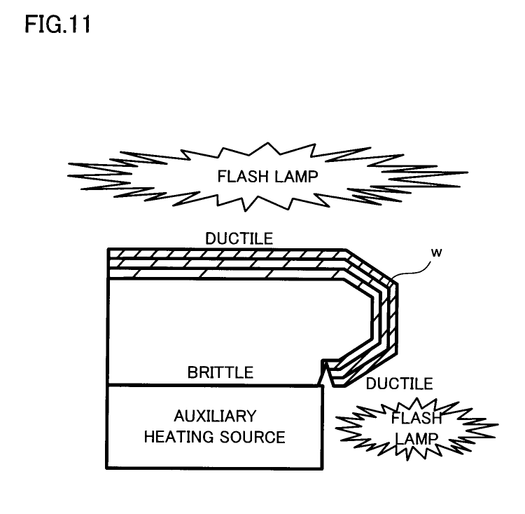

In this embodiment, as illustrated in FIG. 11, by annealing the outer circumferential portion of the rear surface of the semiconductor substrate with the flash lamp light, the outer circumferential portion where the scratches are concentrated can be maintained at the high temperature, and the tensile stress can be suppressed from being generated. The outer circumferential portion of the rear surface of the semiconductor substrate as well as the front surface of the semiconductor substrate can be changed from the brittle region to the ductile region. Accordingly, if the compressive stress is secured and the dislocation is generated before the crack is developed, the thermal stress can be released. It is therefore considered that the semiconductor substrate can be suppressed from being broken.

The heating using the flash lamp light remains in the local heating to the depth of about several tens of micrometers, because the invasion length of the light is short and the heating time is extremely short. Accordingly, in the heating using the flash lamp light from the rear surface, the heat is not transmitted to the front surface of the semiconductor substrate where active layer or the element region exists. It is therefore considered that the in-plane uniformity of the front surface temperature can be secured.

In this embodiment, the outer circumferential portion of the semiconductor substrate is set to within 5 mm from the outer end. However, the temperature of the rear surface within 1 to 5% of the diameter from the outer end of the semiconductor substrate may be controlled. By controlling the positional range to have the temperature range, the tensile stress of the outer circumferential portion can be suppressed from being generated due to the irradiation of the flash lamp light. In addition, although the temperature of the outer circumferential portion of the rear surface of the semiconductor substrate is controlled to be 100° C. higher than the temperature of the central portion, the temperature of the outer circumferential portion may be controlled to be higher than the temperature of the central portion by about 5 to 20% (50 to 200° C. in the case of 1000° C.). By controlling the positional range to have the temperature range, the tensile stress of the outer circumferential portion can be suppressed from being generated due to the irradiation of the flash lamp light.

As described above, according to this embodiment, by irradiating the flash lamp light onto the outer circumferential portion of the rear surface of the semiconductor substrate in synchronization with the irradiation of the flash lamp light onto the front surface of the semiconductor substrate, the irradiation region of the outer circumferential portion of the rear surface can be restricted to a needed region and the annealing temperature can be varied. Accordingly, the cracks can be prevented by suppressing damage such as slip, dislocation, and breakage of the semiconductor substrate and a yield can be improved. The process window can be increased, in-plane uniformity of the front surface temperature in the element formation region needed as a product can be secured, an in-plane variation of an element characteristic can be suppressed, and activation of the high density of the impurity injection layer and shallow junction can be achieved. Accordingly, a semiconductor device having high performance can be stably formed.

### Second Embodiment

In this embodiment, a semiconductor device is formed in the same manner as in the first embodiment except that a method for heating an outer circumferential portion of a rear surface of the semiconductor substrate is different.

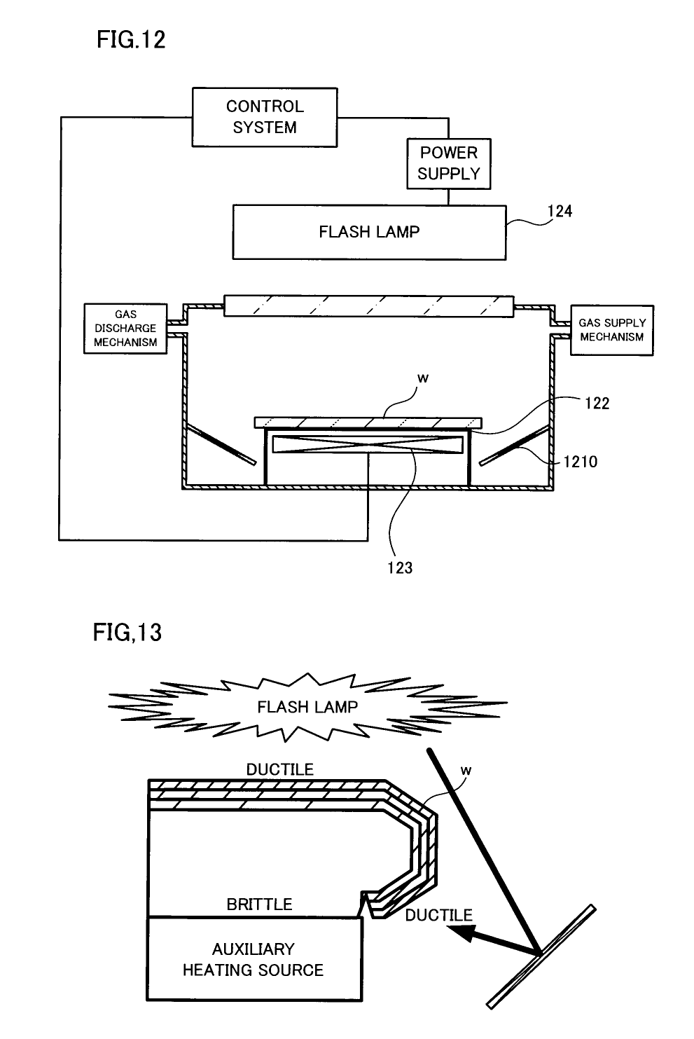

By the same manufacturing process as that in the first embodiment, the impurity injection layer is formed in the semiconductor substrate w. Then, activation annealing is performed using a heat treatment apparatus illustrated in FIG. 12.

The heat treatment apparatus has the same structure as that of the heat treatment apparatus illustrated in FIG. 4, except that a stage 122 has a smaller area than the semiconductor substrate w, that only an auxiliary heating source 123 is disposed below the stage 122, and that a reflecting plate 1210 is provided below an outer circumferential portion of the stage 122, instead of the light source (flash lamp) at the rear surface side of the semiconductor substrate w. As illustrated in FIG. 13, flash lamp light that is emitted from an upper light source 124 is irradiated onto the front surface of the semiconductor substrate w, reflected by the reflecting plate 1210, and irradiated onto the outer circumferential portion of the rear surface of the semiconductor substrate w.

Further, the semiconductor device is formed by the same process as that of the first embodiment.

In this embodiment, the flash lamp light is irradiated onto the front surface of the semiconductor substrate, and the reflective light is irradiated onto the outer circumferential portion of the rear surface. Thereby, damage such as slip, dislocation, and breakage of the semiconductor substrate can be suppressed, cracks can be thus prevented, and a yield can be improved. Accordingly, the same effects as those of the first embodiment can be obtained. Since only one light source (flash lamp) is disposed, a manufacturing cost and a hard load can be reduced.

### Third Embodiment

In this embodiment, a semiconductor device is formed in the same manner as in the first embodiment except that a method for heating an outer circumferential portion of a rear surface of the semiconductor substrate is different.

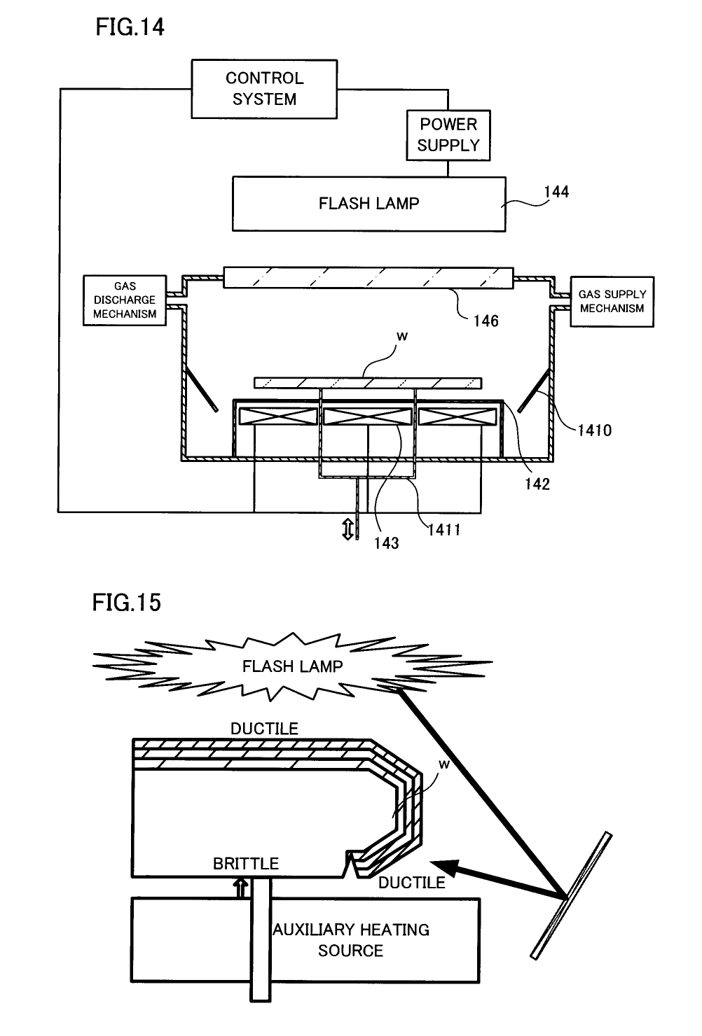

By the same manufacturing process as that in the first embodiment, the impurity injection layer is formed in the semiconductor substrate w. Then, activation annealing is performed using a heat treatment apparatus illustrated in FIG. 14.

The heat treatment apparatus has the same structure as that of the heat treatment apparatus illustrated in FIG. 4, except that an auxiliary heating source 143 is disposed to heat the entire surface of the semiconductor substrate w, that a reflecting plate 1410 is provided below the outer circumferential portion of the stage 142, instead of the light source (flash lamp) at the rear surface side of the semiconductor substrate w, similarly to the second embodiment, and that a lift pin 1411 to move the semiconductor substrate w up and down from the lower side of the stage 142 is provided.

As illustrated in FIG. 15, immediately before irradiating flash lamp light from a light source 144 that is an upper irradiating mechanism, the semiconductor substrate w is lifted by the lift pin 1411 and a gap is formed. The flash lamp light is irradiated onto the front surface of the semiconductor substrate w, reflected by the reflecting plate 1410, and irradiated onto the outer circumferential portion of the rear surface of the semiconductor substrate w.

Further, the semiconductor device is formed by the same process as that of the first embodiment.

In this embodiment, the entire rear surface is auxiliary-heated, the semiconductor substrate is lifted immediately before the flash lamp light is irradiated, the flash lamp light is irradiated onto the front surface of the semiconductor substrate, and the reflective light is irradiated onto the outer circumferential portion of the rear surface. Thereby, damage such as slip, dislocation, and breakage of the semiconductor substrate can be suppressed, cracks can thus be prevented, and a yield can be improved. Accordingly, the same effects as those of the first embodiment can be obtained. Similarly to the second embodiment, since only one light source (flash lamp) is disposed, a manufacturing cost and a hard load can be reduced. Further, since the entire rear surface can be auxiliary-heated, the temperature of the rear surface can be made uniform.

Similarly to the first embodiment, a light source (flash lamp) may be disposed instead of the reflecting plate 1410.

### Fourth Embodiment

In this embodiment, a semiconductor device is formed in the same manner as in the first embodiment except that flash lamp light is irradiated onto the rear surface of the semiconductor substrate, a ductile region is formed in a shallow region of the rear surface, and then the flash lamp light is irradiated onto the front surface of the semiconductor substrate.

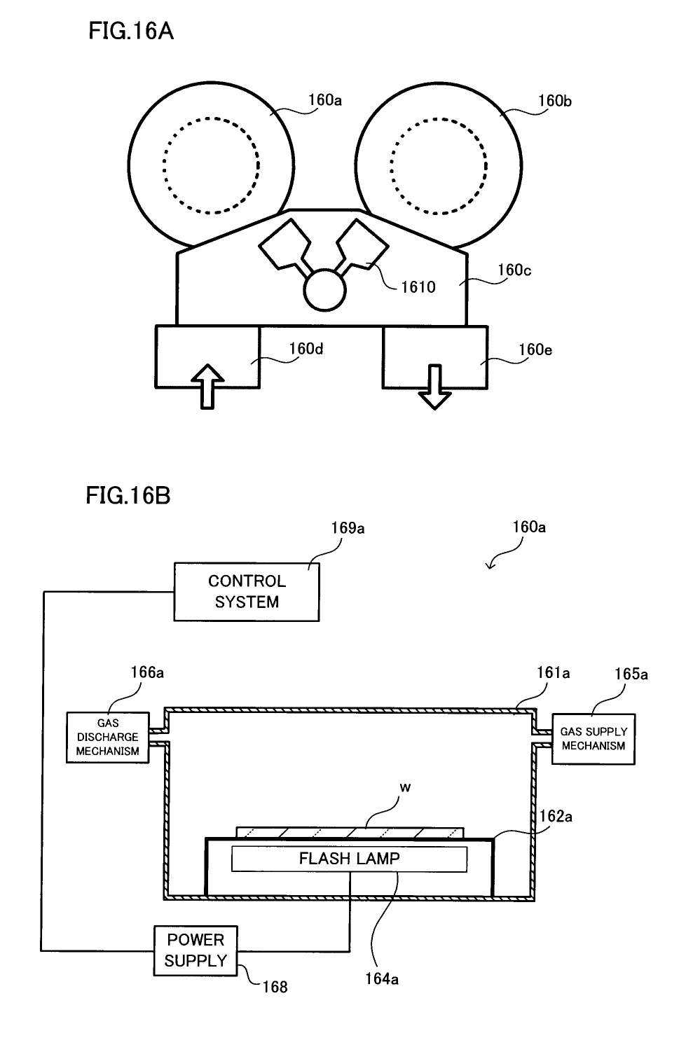

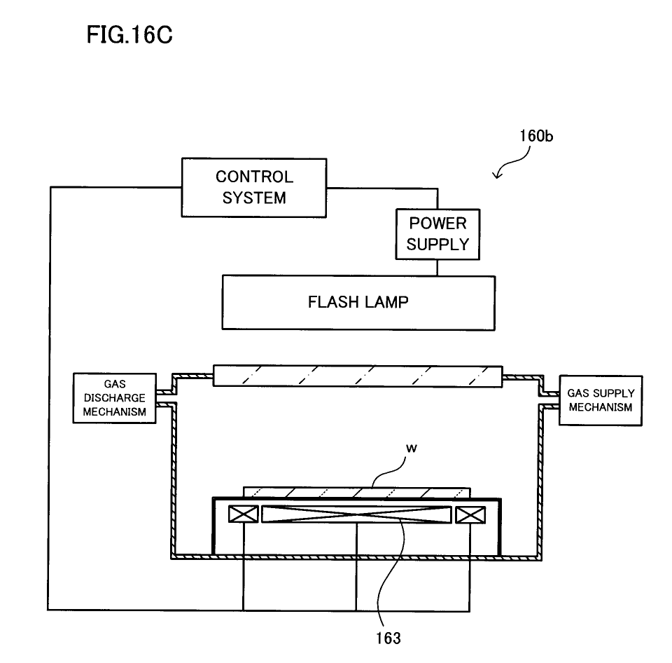

By the same manufacturing process as that in the first embodiment, the impurity injection layer is formed in the semiconductor substrate w. Then, activation annealing is performed using a heat treatment apparatus illustrated in FIG. 16A.

The heat treatment apparatus includes two heat treatment units 160a and 160b, a transfer chamber 160c, and load lock chambers 160d and 160e.

As illustrated in FIG. 16B, in the heat treatment unit 160a, a chamber 161a having the same structure as that in FIG. 4 and a stage 162a to mount the semiconductor substrate w thereon are disposed. In the stage 162a, a light source (flash lamp) 164a that is an irradiating mechanism for heating the semiconductor substrate w from the rear surface is provided. Further, a gas supply mechanism 165a for supplying inert gas or the like into the chamber 161a and a gas discharge mechanism 166a for discharging gas therefrom are provided. The chamber 161a is connected to a power supply 168 and a control system 169a to control an irradiation energy density of the light source 164a.

As illustrated in FIG. 16C, the heat treatment unit 160b has the same structure as that of the heat treatment apparatus illustrated in FIG. 4, except that the auxiliary heating source 163 is disposed to heat the entire surface of the semiconductor substrate wand the light source at the side of the rear surface is not provided.

In the transfer chamber 160c, a transfer mechanism 1610, such as a transfer arm, which carries the semiconductor substrate w from the heat treatment unit 160a to the heat treatment unit 160b, is provided.

In the heat treatment apparatus, activation annealing is performed according to a flow shown in FIG. 17. The semiconductor substrate w where the impurity injection layer is formed is loaded into the chamber 161a of the heat treatment unit 160a and mounts on the stage 162a. The light source 164a is controlled by the control system 169a, the flash lamp light is irradiated onto the rear surface of the semiconductor substrate w under the condition where a pulse width is 1 msec and an irradiation energy density is 30 J/cm² (Step 4-1), the temperature of the rear surface side is increased to, for example, 800° C., and a ductile region is formed. The semiconductor substrate w is unloaded from the heat treatment unit 160a by the transfer mechanism 1610 and loaded into the chamber 161b of the heat treatment unit 160b.

In the chamber 161b, the semiconductor substrate w is mounted on the stage 162b and auxiliary-heated at 500° C. by the auxiliary heating source 163 (Step 4-2). The light source 164b is controlled by the control system 169b, and the flash lamp light is irradiated onto the front surface of the semiconductor substrate w through the transparent window 167 disposed upper part of the chamber 161b under the condition where a pulse width is 1 msec and an irradiation energy density is 30 J/cm² (Step 4-3). By irradiating the flash lamp light in this way, the temperature of the front surface of the semiconductor substrate w is increased to 1200° C.

Further, the semiconductor device is formed by the same process as that of the first embodiment.

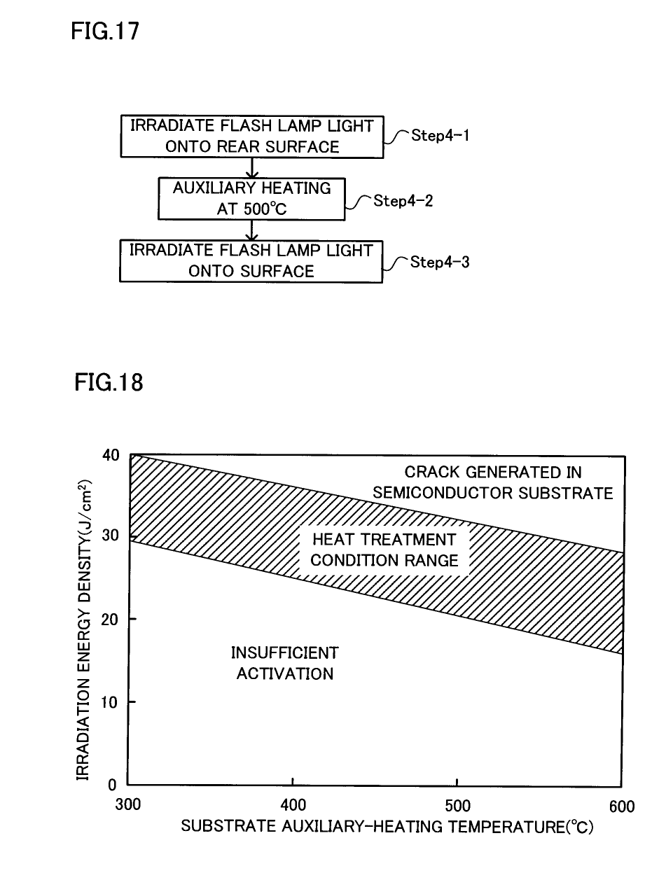

In this embodiment, an irradiation energy density range of the flash lamp light to achieve a desired activation rate in high-temperature activation annealing depends on an auxiliary-heating temperature, and a heat treatment condition range (process window) is as shown in FIG. 18. As compared with the heat treatment condition range (process window) according to the related art shown in FIG. 7, it is found that the heat treatment condition range is widened.

From the above results, the reason why crack resistance of the semiconductor substrate is improved in this embodiment is considered.

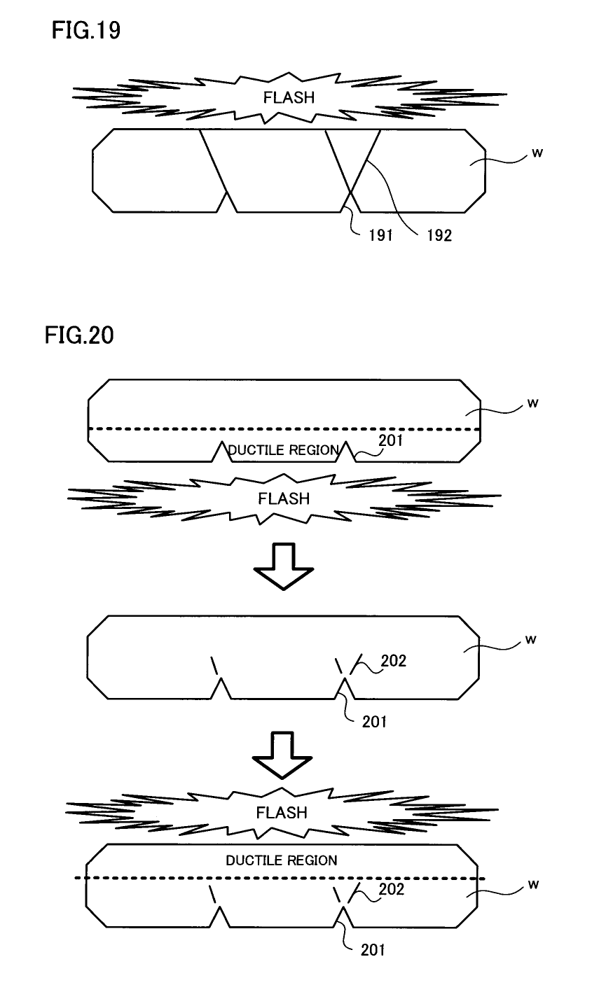

In the rear surface of the semiconductor substrate, scratches are generated due to external causes such as in a device transfer system, and the number of scratches is large. In addition, the tensile stress at the rear surface side of the semiconductor substrate increases due to the temperature difference between the front and rear surfaces of the semiconductor substrate. Since the rear surface side remains in a brittle region at the temperature lower than 600° C., when the thermal stress is concentrated on the outer circumference of the semiconductor substrate, a crack 192 is developed from a scratch 191 to release the thermal stress as illustrated in FIG. 19. As a result, the semiconductor substrate is broken.

In this embodiment, as illustrated in FIG. 20, the flash lamp light is irradiated onto the rear surface side where damage is generated and the rear surface side is heated to 800° C. prior to the irradiation on the front surface of the semiconductor substrate. Therefore, the rear surface side can be changed into the ductile region. As a result, before the development of the crack originating from a scratch 201, a dislocation 202 is generated at an end of the scratch, thereby releasing the stress. That is, by changing the rear surface side into the ductile region, the dislocation is generated without developing the scratch, and a stress concentration coefficient can be lowered. It is thus considered that the strength of the semiconductor substrate can be improved.

As means for generating the dislocation in a rear surface scratch of the semiconductor substrate, the high-temperature annealing may be used to form a ductile region in the rear surface of the semiconductor substrate.

However, excessively-long annealing time affects an active layer of the front surface side. That is, since an activation rate or a depth of the active layer is varied, an electrical characteristic of the MOSFET is varied. As described above, in the heating using the flash lamp light, the invasion length of the light is short and the heating time is extremely short. For this reason, the rapid temperature rise is locally generated in the region within several tens of micrometers. However, by the heating from the rear surface, the heat is not transmitted to the active layer formed at the front surface side. Accordingly, the electrical characteristic of the MOSFET is not affected.

In this embodiment, the flash lamp light is irradiated onto the rear surface of the semiconductor substrate, the ductile region is formed in the shallow region of the rear surface, and then the flash lamp light is irradiated onto the front surface of the semiconductor substrate. Thereby, damage such as slip, dislocation, and breakage of the semiconductor substrate can be suppressed, cracks can be thus prevented, and a yield can be improved. Accordingly, the same effects as those of the first embodiment can be obtained.

### Fifth Embodiment

In this embodiment, a semiconductor device is formed in the same manner as in the fourth embodiment except that a method for heating the rear surface of the semiconductor substrate is different.

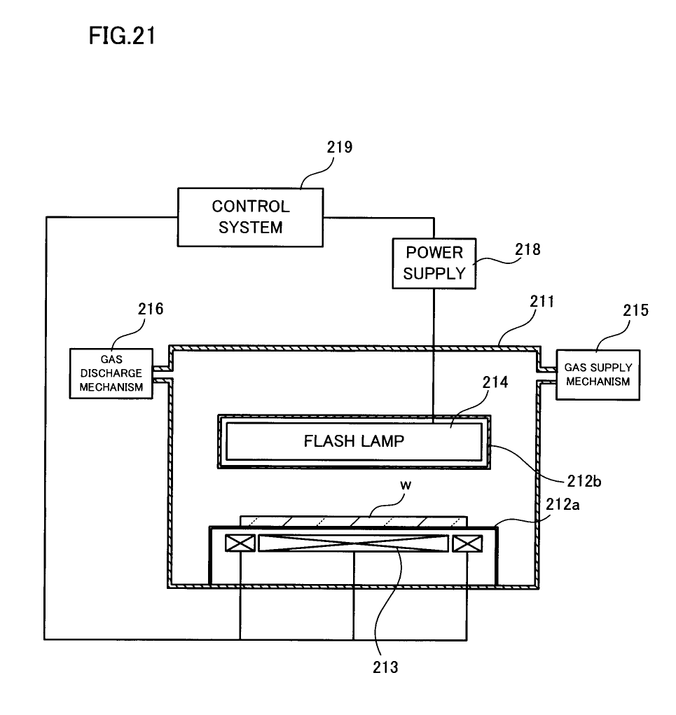

By the same manufacturing process as that in the first embodiment, the impurity injection layer is formed in the semiconductor substrate w. Then, activation annealing is performed using a heat treatment apparatus illustrated in FIG. 21.

In the heat treatment apparatus, in a chamber 211, stages 212a and 212b to mount the semiconductor substrate w thereon are disposed. The stages 212a and 212b have the same structure as that of the heat treatment apparatus illustrated in FIG. 4. In the stage 212a, an auxiliary heating source 213 is provided to auxiliary-heat the entire rear surface of the semiconductor substrate w. In the stage 212b, a light source (flash lamp) 214 that is an irradiating mechanism for heating the semiconductor substrate w mounted on the stage 212a from the front surface and heat the semiconductor substrate w mounted on the stage 212b from the rear surface is disposed. In the heat treatment apparatus, a gas supply mechanism 215 for supplying inert gas or the like into the chamber 211 and a gas discharge mechanism 216 for discharging gas therefrom are provided. Further, a transfer mechanism (not illustrated), such as a transfer arm, which carries the semiconductor substrate w from the stage 212b to the stage 212a, is provided.

The light source 214 is connected to a power supply 218 and a control system 219 to control an irradiation energy density of the light source 214 and an output of the auxiliary heating source 213.

Similarly to the fourth embodiment, activation annealing is performed according to the flow shown in FIG. 17. First, the semiconductor substrate w where the impurity injection layer is formed is loaded into the chamber 211 and mounted on the stage 212b. The light source 214 is controlled by the control system 219, the flash lamp light is irradiated onto the rear surface of the semiconductor substrate w under the condition where a pulse width is 1 msec and an irradiation energy density is 30 J/cm² (Step 4-1), the temperature of the rear surface side is increased to 800° C., and a ductile region is formed. The semiconductor substrate w is transferred from the stage 212b to the stage 212a by a transfer mechanism (not illustrated).

The semiconductor substrate w that is mounted on the stage 212a is auxiliary-heated at 500° C. by the auxiliary heating source 213 (Step 4-2). The light source 214 is controlled by the control system 219, and the flash lamp light is irradiated onto the front surface of the semiconductor substrate w under the condition where a pulse width is 1 msec and an irradiation energy density is 30 J/cm² (Step 4-3). By irradiating the flash lamp light in this way, the temperature of the front surface of the semiconductor substrate w is increased to 1200° C.

Further, the semiconductor device is formed by the same process as that of the first embodiment.

In this embodiment, similarly to the fourth embodiment, the flash lamp light is irradiated onto the rear surface of the semiconductor substrate, the ductile region is formed in the shallow region of the rear surface, and then the flash lamp light is irradiated onto the front surface of the semiconductor substrate. Thereby, damage such as slip, dislocation, and breakage of the semiconductor substrate can be suppressed, cracks can be thus prevented, and a yield can be improved. Accordingly, the same effects as those of the first embodiment can be obtained. In addition, while two heat treatment apparatuses need to be provided in the fourth embodiment, one heat treatment apparatus may be sufficient in this embodiment. Since the front and rear surfaces of each of the two semiconductor substrates can be heated by driving one light source (flash lamp), a manufacturing cost and a hard load can be reduced.

### Sixth Embodiment

In this embodiment, a semiconductor device is formed in the same manner as in the fourth embodiment except that a method for heating the rear surface of the semiconductor substrate is different.

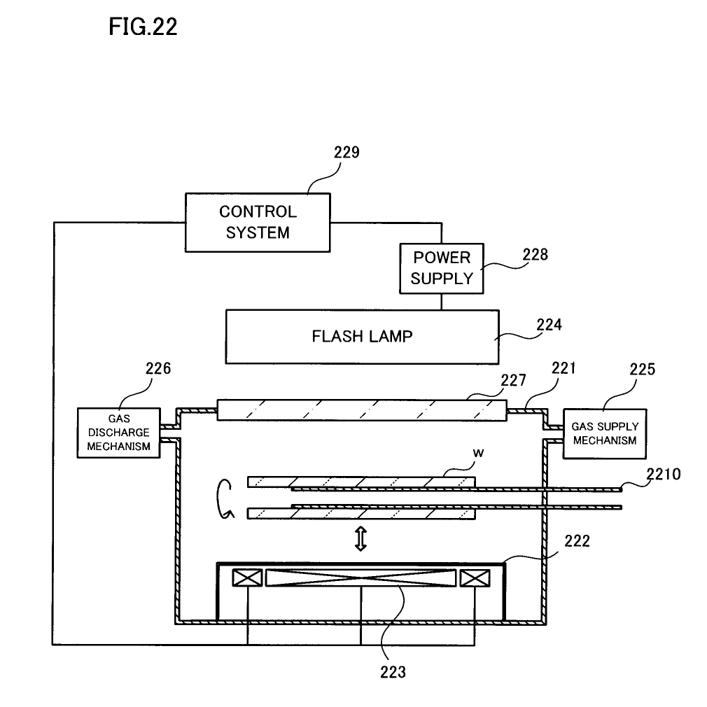

By the same manufacturing process as that in the first embodiment, the impurity injection layer is formed in the semiconductor substrate w. Then, activation annealing is performed using a heat treatment apparatus illustrated in FIG. 22.

In the heat treatment apparatus, in a chamber 221, a stage 222 to mount the semiconductor substrate w thereon is disposed. The stage 222 has the same structure as that of the heat treatment apparatus illustrated in FIG. 4. In the stage 222, an auxiliary heating source 223 is provided to auxiliary-heat the entire rear surface of the semiconductor substrate w. In the heat treatment apparatus, a gas supply mechanism 225 for supplying inert gas or the like into the chamber 221 and a gas discharge mechanism 226 for discharging gas therefrom are provided. Further, a reversing mechanism 2210 that includes a reversing arm having a chuck function to reverse the semiconductor substrate w is provided.

Above the chamber 221, a light source (flash lamp) 224 that is an irradiating mechanism is provided at a distance from the chamber 221 for irradiating emission light in the chamber 221 through the transparent window 227, in a state where airtightness of the chamber 221 is held, to heat the semiconductor substrate w. The light source 224 is connected to a power supply 228 and a control system 229 for controlling an irradiation energy density of the light source 224 and an output of the auxiliary heating source 223.

Similarly to the fourth embodiment, activation annealing is performed according to the flow shown in FIG. 17. First, the semiconductor substrate w where the impurity injection layer is formed is loaded into the chamber 221 and mounted on the stage 222. The light source 224 is controlled by the control system 229, the flash lamp light is irradiated onto the rear surface of the semiconductor substrate w under the condition where a pulse width is 1 msec and an irradiation energy density is 30 J/cm² (Step 4-1), the temperature of the rear surface side is increased to, for example, 800° C., and a ductile region is formed. The semiconductor substrate w is reversed by the reversing mechanism 2210 and mounted on the stage 222 again.

The semiconductor substrate w that is mounted on the stage 222 is auxiliary-heated at 500° C. by the auxiliary heating source 223 (Step 4-2). The light source 224 is controlled by the control system 229, and the flash lamp light is irradiated onto the front surface of the semiconductor substrate w under the condition where a pulse width is 1 msec and an irradiation energy density is 30 J/cm² (Step 4-3). By irradiating the flash lamp light in this way, the temperature of the front surface of the semiconductor substrate w is increased to 1200° C.

Further, the semiconductor device is formed by the same process as that of the first embodiment.

In this embodiment, similarly to the fourth embodiment, the flash lamp light is irradiated onto the rear surface of the semiconductor substrate, the ductile region is formed in the shallow region of the rear surface, and then the flash lamp light is irradiated onto the front surface of the semiconductor substrate. Thereby, damage such as slip, dislocation, and breakage of the semiconductor substrate can be suppressed, cracks can be thus prevented, and a yield can be improved. Accordingly, the same effects as those of the first embodiment can be obtained. In addition, while two heat treatment apparatuses need to be provided in the fourth embodiment, one heat treatment apparatus may be sufficient in this embodiment. Accordingly, a manufacturing cost and a hard load can be reduced.

In this embodiment, the auxiliary-heating temperature at the time of activation annealing is appropriately set. However, the temperature and the time that do not induce damage to the semiconductor substrate may be set. For example, the temperature in a range of 300 to 700° C. and the heating time in a range of 10 to 120 sec need to be set.

If the auxiliary-heating temperature is lower than 300° C., the highest reached temperature becomes lower than 900° C., and activation of the impurities that are injected into the semiconductor substrate becomes insufficient. On the other hand, if the auxiliary-heating temperature exceeds 700° C., the reached temperature may exceed 1400° C. Since the time during which the semiconductor substrate that is exposed at the high temperature of 1000° C. or more increases, the diffusion length of the injected impurity exceeds 5 nm, and it becomes difficult to form a shallow pn junction of 20 nm or less in the vicinity of the surface. Further, since a short channel effect is induced, ON/OFF control of a minute transistor becomes impossible.

Preferably, a temperature range of 500 to 700° C. is set. In particular, the higher temperature of 600° C. or more is preferable. This is because, when the temperature is high, the rear surface of the semiconductor substrate becomes a ductile region, and the dislocation is easily released from the end of the scratch.

In these embodiments, the rising and falling time of the temperature at the front surface of the semiconductor substrate in a range of 450 to 1300° C. is preferably in a range of 0.1 to 100 msec. If the temperature rising and falling time is shorter than 0.1 msec, the highest reached temperature becomes lower than 900° C., and activation of the impurity that is injected into the semiconductor substrate becomes insufficient. On the other hand, if the temperature rising and falling time exceeds 100 msec, the reached temperature may exceed 1400° C. As described above, it becomes difficult to form a shallow pn junction in the vicinity of the surface. More preferably, the temperature rising and falling time is in a range of 0.5 to 50 msec. The irradiation energy density may be controlled in a range of, for example, 10 to 50 J/cm², preferably, a range of 15 to 35 J/cm².

### Seventh Embodiment

In this embodiment, a semiconductor device is formed in the same manner as in the first embodiment except that the heat treatment using the flash lamp light is performed on the front surface only and in two steps.

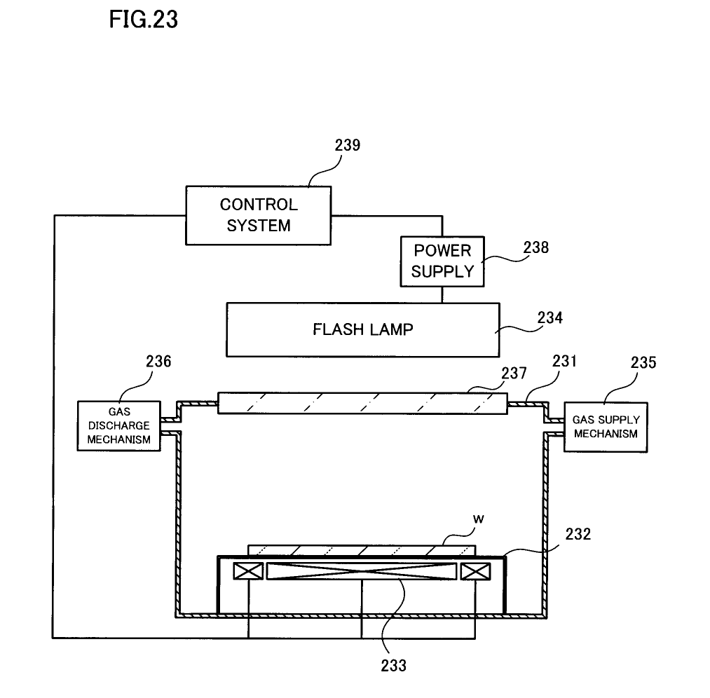

By the same manufacturing process as that in the first embodiment, the impurity injection layer is formed in the semiconductor substrate w. Then, activation annealing is performed using a heat treatment apparatus illustrated in FIG. 23.

In the heat treatment apparatus, in a chamber 231, a stage 232 to mount the semiconductor substrate w thereon is disposed. The stage 232 has the same structure as that of the heat treatment apparatus illustrated in FIG. 4. In the stage 232, an auxiliary heating source 233 is provided to auxiliary-heat the entire rear surface of the semiconductor substrate w. Further, a gas supply mechanism 235 for supplying inert gas or the like into the chamber 231 and a gas discharge mechanism 236 for discharging gas therefrom are provided.

Above the chamber 231, a light source (flash lamp) 234 is provided at a distance from the chamber 231 for irradiating emission light in the chamber 231 through the transparent window 237, in a state where airtightness of the chamber 231 is held, to heat the semiconductor substrate w. The light source 234 is connected to a power supply 238 and a control system 239 for controlling an irradiation energy density of the light source 234 and an output of the auxiliary heating source 233.

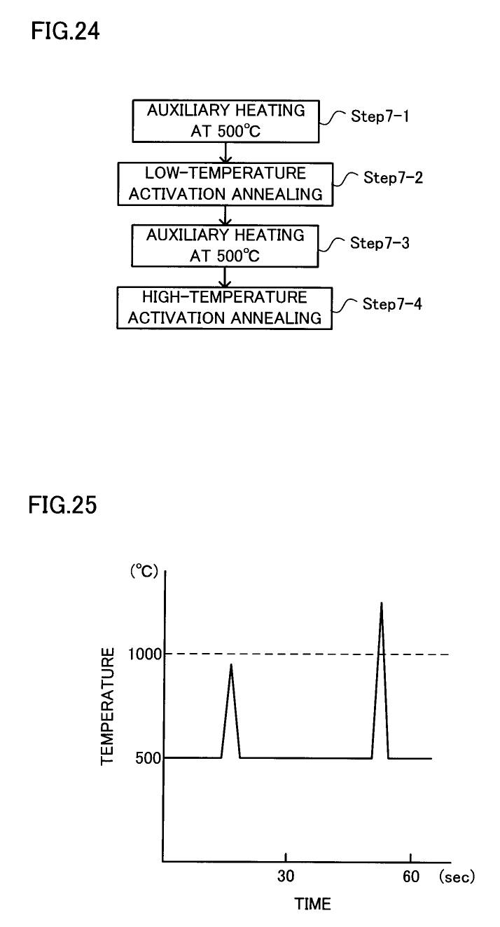

Similarly to the fourth embodiment, activation annealing is performed according to a flow shown in FIG. 24 and a thermal history shown in FIG. 25.

First, the semiconductor substrate w is auxiliary-heated from the rear surface at 500° C. in advance (Step 7-1). In a state where the temperature rising and falling time is maintained for about 10 sec, first activation annealing (hereinafter, referred to as low-temperature activation annealing) is performed by irradiating the flash lamp light onto the front surface of the semiconductor substrate w under the condition where a pulse width (half-value width) is 1 msec and an irradiation energy density is 18 J/cm², such that the temperature of the front surface becomes 1000° C. or less, for example, about 950° C. (Step 7-2).

The semiconductor substrate w is auxiliary-heated from the rear surface at 500° C. (Step 7-3). In a state where the temperature rising and falling time is maintained at about 30 sec, second activation annealing (hereinafter, referred to as high-temperature activation annealing) is performed by irradiating the flash lamp light onto the front surface of the semiconductor substrate w under the condition where a pulse width (half-value width) is 1 msec and an irradiation energy density is 30 J/cm², such that the temperature of the front surface becomes 1200° C. or more that is higher than that in low-temperature activation annealing (the first activation annealing), for example, about 1250° C. (Step 7-4).

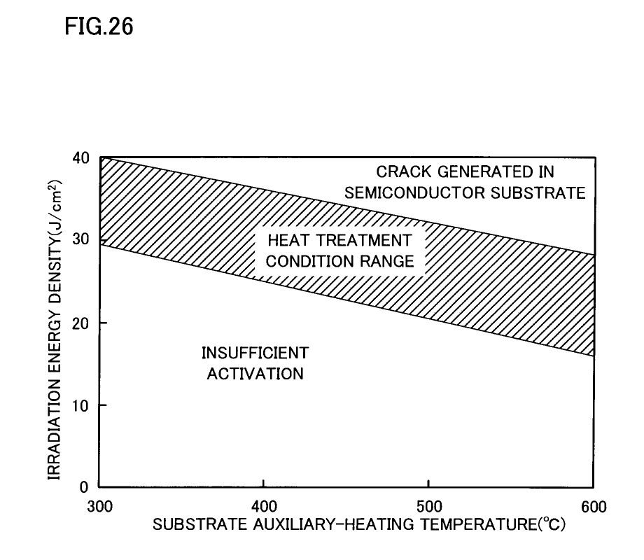

When the high-temperature activation annealing is performed after the low-temperature annealing, dislocation or crystal defect can be suppressed from being generated, and the crack of the semiconductor substrate can be suppressed from being generated and can achieve a desired activation rate. The irradiation energy density range of the flash lamp in such the high-temperature activation annealing depends on the auxiliary heating temperature, and the heat treatment condition range (process window) is as shown in FIG. 26. As compared with the heat treatment condition range (process window) according to the related art shown in FIG. 7, the heat treatment condition range is widened.

In the manufacturing process of the semiconductor device, several hundred of processes, such as a cleaning process, a CVD process, a lithographic process, and an RIE process, are carried out before the impurity ion injecting process. Thus, during a transfer process or processing, a large amount of damages are generated in the rear surface of the semiconductor substrate extending the depth of several micrometers. For this reason, when the activation annealing is performed using the flash lamp, the tensile stress applied to the rear surface side increases due to the temperature difference between the front and rear surfaces of the semiconductor substrate, and the tensile stress is concentrated on the damages of the rear surface.

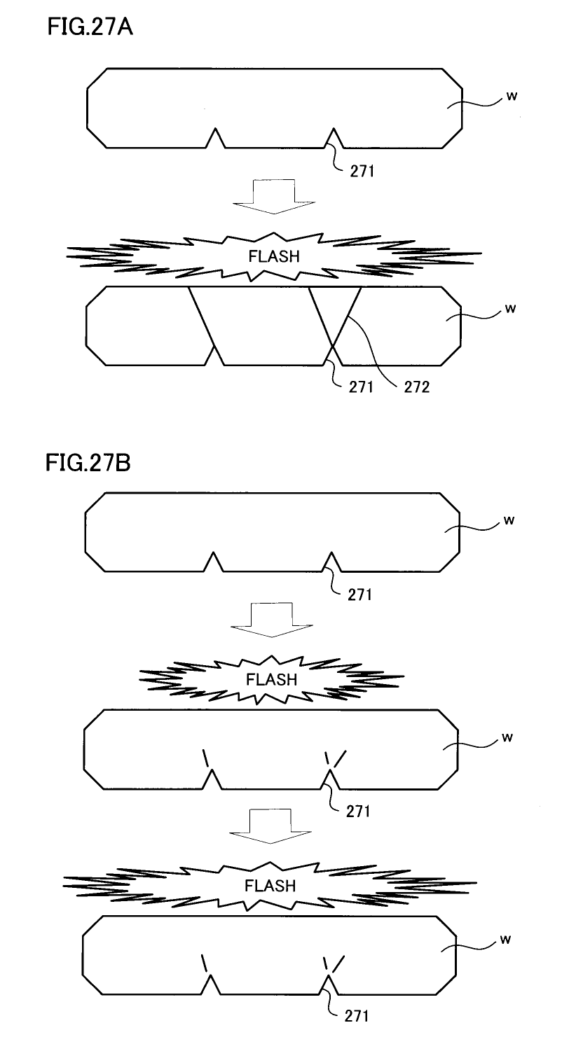

For example, when the high-temperature activation annealing is performed without performing the low-temperature activation annealing, the tensile stress applied to the rear surface side that is estimated based on a thermal stress calculation becomes about 150 MPa. When damage where the curvature radius is 1 μm and the depth is 10 μm is generated in the rear surface, the tensile stress that is about seven times as strong as the existing tensile stress is concentrated on the damage. Accordingly, since the tensile stress in the damage exceeds 1 GPa corresponding to the breakage stress of Si, a crack 272 that starts from a place of damage 271 is developed, the stress is released, and the semiconductor substrate is broken as illustrated in FIG. 27A.

On the other hand, when the high-temperature activation annealing is performed after the low-temperature activation annealing is performed, the tensile stress applied to the rear surface side that is estimated based on a thermal stress calculation is suppressed to about 100 MPa. Thus, even when the damage 271 where the curvature radius is 1 μm and the depth is 10 μm is generated in the rear surface, the tensile stress in the damage remains in the concentration of the stress not more than 1 GPa corresponding to the breakage stress of Si. Accordingly, the semiconductor substrate is not broken.

The reason is considered as follows. As illustrated in FIG. 27B, force that does not cause the semiconductor substrate to be cracked is applied to the end of the damage by the low-temperature activation annealing, and the dislocation is released from the peripheral portion of the end of the damage 271. By the low-temperature activation annealing, the compressive stress as a reaction to the tensile stress is added, and the form of the damage is changed, such as a change that the crack of the end of the damage is adhered. That is, the dislocation is released from the damage and the effective crack length is shortened, and the curvature radius of the damage increases and the depth decreases. As a result, the stress concentration coefficient becomes small, and the stress concentration on the damage can be alleviated.

Accordingly, the condition of the low-temperature activation annealing needs to be set to suppress the stress concentration on the damage. Specifically, the condition needs to be set such that the tensile stress concentration does not exceed 1 GPa corresponding to the breakage stress of Si. For example, the auxiliary-heating temperature and the irradiation energy density may be appropriately set such that the front surface temperature of the semiconductor substrate becomes 1000° C. or less.

In this embodiment, the low-temperature activation annealing condition where the front surface temperature of the semiconductor substrate w is about 950° C., the pulse width (half-value width) is 1 msec, and the irradiation energy density is 18 J/cm² is set, and the high-temperature activation annealing condition where the front surface temperature of the semiconductor substrate w is about 1250° C., the pulse width (half-value width) is 1 msec, and the irradiation energy density is 30 J/cm² is set. However, the low-temperature activation annealing condition and the high-temperature activation annealing condition are not limited to the above conditions.

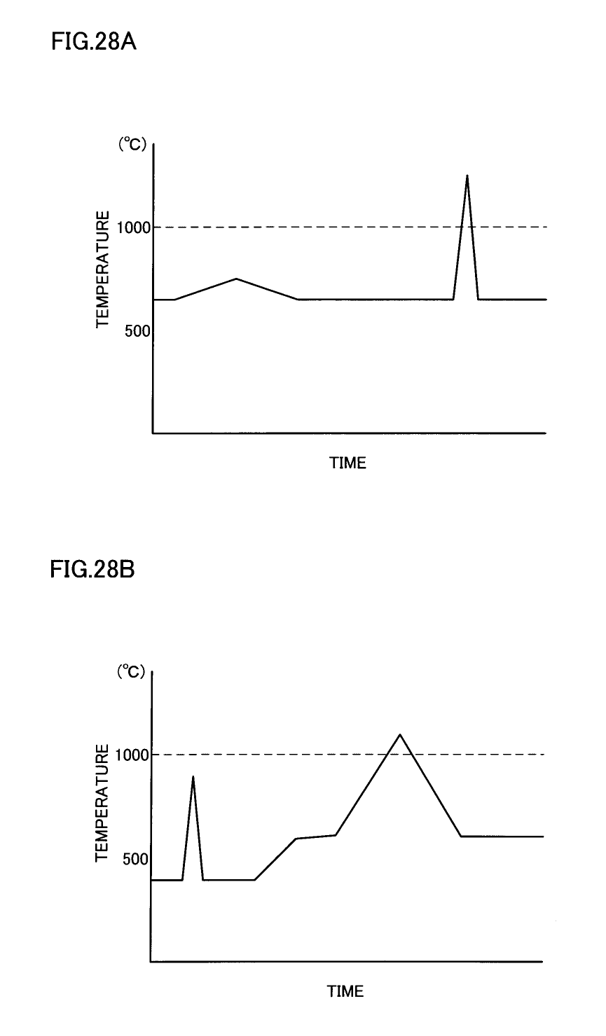

In order to suppress the stress concentration on the damage, the irradiation time of the flash lamp light in the low-temperature activation annealing may be set to be longer than the irradiation time in the high-temperature activation annealing as shown in the thermal history in FIG. 28A. On the other hand, when the irradiation intensity of the flash lamp light in the low-temperature activation annealing is set to be higher, the irradiation time may be set to be shorter than the irradiation time in the high-temperature activation annealing as shown in FIG. 28B. That is, the irradiation energy density in the low-temperature activation annealing may be set to become smaller than the irradiation energy density in the high-temperature activation annealing, and the temperature of the front surface of the semiconductor substrate in the low-temperature activation annealing may be set to become lower than the temperature of the front surface of the semiconductor substrate in the high-temperature activation annealing.

The timing when the high-temperature activation annealing is performed may be timing after the form of the damage of the rear surface of the semiconductor substrate is changed by the low-temperature activation annealing. Since the total thermal amount can be increased, the flash lamp may be intermittently turned on at a time interval of the irradiation time or more.

Further, the semiconductor device is formed by the same process as that in the first embodiment.

In this embodiment, cracks can be prevented by suppressing damage such as slip, dislocation, and breakage of the semiconductor substrate by the heat treatment in two stages from the front surface, and a yield can be improved. Accordingly, the same effect as that of the first embodiment can be obtained.

In this embodiment, the auxiliary-heating temperature is set to 500° C. However, similarly to the sixth embodiment, the temperature and the time that do not cause the damage to the semiconductor substrate may be set.

The embodiment may be applied to heat treatment other than the activation annealing after the impurity is injected. For example, the embodiment may be applied to formation of an insulating film, such as an oxide film and a nitride film, a conversion of amorphous Si or poly-Si crystal into single crystal, and a heat treatment process to grow crystal.

In this embodiment, the activation annealing using the flash lamp light is performed. However, the irradiating mechanism (light source) is preferably a Xe flash lamp. However, the irradiating mechanism is not limited to the Xe flash lamp, and may be any light source capable of high-luminance emission, such as a flash lamp using other rare gas, mercury, or hydrogen, laser, such as excimer laser, YAG laser, carbon monoxide (CO) laser or carbon dioxide (CO₂) laser, or a light source, such as a Xe arc discharge lamp. If the temperature rising and falling rate can be controlled at a high speed, the embodiment may be applied to the case where the heat treatment is performed using the halogen lamp and a resistance heating heater according to related art.

In this embodiment, the p-type Si substrate is used as the semiconductor substrate, but a bulk single crystal wafer is not necessarily used. An epitaxial wafer or an SOI wafer may also be used.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A manufacturing method for a semiconductor device, comprising:
forming an element region on a front surface of a semiconductor substrate;
performing a first heat treatment by irradiating first irradiation light having a first irradiation energy density onto the front surface of the semiconductor substrate with a pulse width of 0.1 to 100 msec at the temperature of 1000° C. or less; and
performing a second heat treatment by irradiating second radiation light having a second irradiation energy density onto the surface of the semiconductor substrate with a pulse width of 0.1 to 100 msec at the temperature higher than the temperature in the first heat treatment.

2. The manufacturing method for a semiconductor device according to claim 1,
wherein the element region includes an impurity injection layer.

3. The manufacturing method for a semiconductor device according to claim 1,
wherein a rear surface of the semiconductor substrate is auxiliary-heated before the first irradiation light is irradiated.

4. The manufacturing method for a semiconductor device according to claim 3,
wherein the auxiliary heating is performed at the temperature of 300 to 700° C.

5. The manufacturing method for a semiconductor device according to claim 3,
wherein the auxiliary heating is performed for 10 to 120 sec.

6. The manufacturing method for a semiconductor device according to claim 1,
wherein the first irradiation light is irradiated to be a stress concentration of 1 GPa or less to a damage of the semiconductor substrate.

7. The manufacturing method for a semiconductor device according to claim 1,
wherein the first irradiation energy density is smaller than the second irradiation energy density.

8. A manufacturing method for a semiconductor device, comprising:
forming an element region on a front surface of a semiconductor substrate;
irradiating first irradiation light having a predetermined irradiation energy density onto a rear surface of the semiconductor substrate with a pulse width of 0.1 to 100 msec to form a ductile region on the rear surface of the semiconductor substrate; and
performing a heat treatment by irradiating second irradiation light having a predetermined irradiation energy density onto the surface of the semiconductor substrate with a pulse width of 0.1 to 100 msec after forming the ductile region.

9. The manufacturing method for a semiconductor device according to claim 8,
wherein the element region includes an impurity injection layer.

10. The manufacturing method for a semiconductor device according to claim 9,
wherein the rear surface of the semiconductor substrate is auxiliary-heated before the first irradiation light is irradiated.

11. The manufacturing method for a semiconductor device according to claim 10,
wherein the auxiliary heating is performed at the temperature of 300 to 700° C.

12. The manufacturing method for a semiconductor device according to claim 10,
wherein the auxiliary heating is performed for 10 to 120 sec.

13. The manufacturing method for a semiconductor device according to claim 8,
wherein the first irradiation light is irradiated from a first light source and the second irradiation light is irradiated from a second light source different from the first light source.

14. The manufacturing method for a semiconductor device according to claim 8,
wherein the first irradiation light is irradiated from a first light source in a first direction; and
the second irradiation light is irradiated from the first light source in a second direction different from the first direction; further comprising:
transferring the semiconductor substrate irradiated the first irradiation light before irradiating the second irradiation light.

15. The manufacturing method for a semiconductor device according to claim 9,
wherein the first irradiation light is irradiated from a first light source in a first direction; and
the second irradiation light is irradiated from the first light source in a second direction different from the first direction; further comprising:
reversing the semiconductor substrate irradiated the first irradiation light before irradiating the second irradiation light.

16. A heat treatment apparatus, comprising:
one or more chambers configured to perform heat treatment to a semiconductor substrate having an element region on a front surface;
one or more stages on which the semiconductor substrate is mounted, disposed in the one or more chambers;
irradiation mechanism configured to irradiate a first irradiation light having a predetermined irradiation energy density with a pulse width of 0.1 to 100 msec onto a rear surface of the semiconductor substrate, and a second irradiation light having a predetermined irradiation energy density with a pulse width of 0.1 to 100 msec onto a front surface of the semiconductor substrate on which the first irradiation light is irradiated;
a movement mechanism configured to transfer or reverse the semiconductor substrate.

17. The heat treatment apparatus according to claim 16,
wherein the one or more chambers includes a first chamber configured to perform heat treatment to the rear surface of the semiconductor substrate, and a second chamber configured to perform heat treatment to the front surface of the semiconductor substrate;
the one or more stages includes a first stage disposed in the first chamber, and a second stage disposed in the second chamber;
the irradiation mechanism includes a first irradiation mechanism disposed under the first stage and the first irradiation mechanism configured to irradiate the first irradiation light, and a second irradiation mechanism disposed above the second stage and the second irradiation mechanism configured to irradiate the second irradiation light;
the movement mechanism is a transfer mechanism configured to transfer the semiconductor substrate from the first chamber to the second chamber.

18. The heat treatment apparatus according to claim 16,
wherein the one or more stages includes a first stage disposed above the irradiation mechanism and a second stage disposed under the irradiation mechanism, the first stage and the second stage disposed in a same chamber; and
the movement mechanism is a transfer mechanism configured to transfer the semiconductor substrate from the first stage to the second stage.

19. The heat treatment apparatus according to claim 16,
wherein the movement mechanism is a reversal mechanism configured to reverse the semiconductor substrate.
